(19) United States
(12) Patent Application Publication
(10) Pub. No.: US 2026/0198157 A1
(43) Pub. Date: Jul. 9, 2026

(54) OPTOELECTRONIC DEVICE AND METHOD FOR MANUFACTURING SAME

(71) Applicant: ALEDIA, Champagnier (FR)

(72) Inventor: Frédéric MAYER, Moirans (FR)

(73) Assignee: ALEDIA, Champagnier (FR)

(21) Appl. No.: 19/134,409

(22) PCT Filed: Nov. 29, 2023
(86) PCT No.: PCT/EP2023/083449

§ 371 Date: May 30, 2025

(30) Foreign Application Priority Data
Dec. 2, 2022 (FR) FR2212706

(51) Int. Cl. H10H 29/49; H10H 20/01; H10H 20/825; H10H 29/01

(52) U.S. Cl. CPC H10H 29/49; H10H 20/019; H10H 20/825; H10H 29/012; H10H 29/0361; H10H 29/0364

(57) ABSTRACT

An optoelectronic device includes a control portion and an optical portion connected together, wherein the control portion includes an electronic component level, and an electrical interconnection level at the front face, the optical portion includes an optically-active component level and an electrical connection level defining a connection face. The control portion includes through connections extending from the interconnection level to a rear face of the control portion, the rear face corresponding to the connection face of the optical portion, so that the electrical interconnection level of the control portion is connected to the electrical connection level of the optical portion via the through connections.

### TECHNICAL FIELD

The present invention relates to the field of technologies for optoelectronics. It finds as a particularly advantageous application testing and manufacture of optoelectronic devices comprising control electronics, for example “smart pixels” based on light-emitting diodes.

### PRIOR ART

A self-emissive display screen is an example of a known optoelectronic system. Such a screen comprises a plurality of pixels emitting their own light. Thus, each pixel is typically formed by one or more LED(s) or micro-LED(s). Each LED may be controlled individually thanks to control electronics derived from the CMOS technology (a technology based on the use of complementary metal-oxide-semiconductor (MOS) transistors). A LED associated with its control electronics is typically called smart LED. A pixel comprising several LEDs associated with at least one control electronics is called smart pixel.

The structure resulting from the combination of LEDs with a control electronics is likened to a vertical stack comprising a an optically-active stage based on LEDs on top of a control stage based on electronic components, the LEDs and the electronic components being interconnected by electrical connections between contact areas of the control stage, called CMOS pads, and contact areas of the optically-active stage.

However, sometimes, the control stage could be defective, for example when some electronic components have defects or sub-nominal performances. To avoid manufacturing defective smart LEDs or smart pixels, a prior test of the control electronics is desirable. Such a prior test step typically allows limiting the subsequent repair costs, during the manufacture of the display screen for example.

The optically active stage, abbreviated optical stage, is firstly formed partially over a dedicated substrate, through first manufacturing steps. In particular, these first manufacturing steps comprise forming the LEDs and forming connections and contact areas for these LEDs, at a so-called the connection face of the optical stage.

The electronic components of the control stage are typically formed over a silicon substrate at the “front face”. The interconnections and the contact pads of the control stage are also formed at the front face.

During the association of the control stage with the optical stage, this front face is set opposite the connection face bearing the contact areas of the LEDs. Afterwards, bonding is performed between these two faces. The silicon substrate is then removed and through contact vias are formed from the “rear face” of the control stage to the front face. Contact pads at the rear face are then made. These contact pads at the rear face allow testing the electronic components of the control stage, typically by placing test probes on these contact pads.

This solution allows preserving a surface condition of the front face compatible with direct bonding. Indeed, contact probes are known to generate a considerable roughness, up to about 3 μm from one peak to another, making a subsequent step of direct bonding at the tested face difficult and expensive.

A drawback of this solution is that testing of the electronic components of the control stage takes place after bonding. When the tested control stage turns out to be defective, it is difficult, and even impossible, to separate it from the optical stage with which it is associated. This makes the process of manufacturing smart LEDs or smart pixels long, complex and expensive.

The present invention aims to overcome at least partially the drawback(s) of the aforementioned solutions.

In particular, an object of the present invention is to provide a method for manufacturing an optoelectronic device comprising an optical stage and a control stage associated together. According to one object, this manufacturing method allows testing the control stage separately form the optical stage and/or prior to the association of the optical and control stages. Another object of the present invention is to provide a method for manufacturing an optoelectronic device whose duration and/or cost are reduced. Another object of the present invention is to provide such an optoelectronic device.

The other objects, features and advantages of the present invention will appear upon examining the following description and the appended drawings. It should be understood that other advantages may be incorporated. In particular, some features and some advantages of the manufacturing method may apply mutatis mutandis to the optoelectronic device, and vice versa.

### SUMMARY

To achieve the above-mentioned objectives, one aspect relates to an optoelectronic device comprising a control portion and an optically-active portion, so-called the optical portion, stacked according to a stacking direction z.

The control portion comprises at least:
a level of electronic components configured to execute logical functions, and
a level of electrical interconnections connected to said electronic component level and defining a first face of the control portion, so-called the front face.

The optical portion comprises at least:
a level of optically-active components configured to emit or receive a light radiation,
a level of electrical connections connected to said optically-active component level and defining a second face of the optical portion, so-called the connection face.

The control portion and the optical portion are associated so that the electrical interconnection level of the control portion is electrically connected to the electrical connection level of the optical portion.

Advantageously, the control portion comprises so-called through connections extending from the interconnection level to a second face of the control portion opposite to the first face, so-called the rear face.

Advantageously, said rear face of the control portion corresponds to the connection face of the optical portion, so that the electrical interconnection level of the control portion is electrically connected to the electrical connection level of the optical portion via said through connections. In this optoelectronic device, the front face of the control portion remains accessible and does not contribute to interfacing with the optical portion. Hence, the control portion could be tested via this front face. Since the front face does not receive the optical portion, the control portion could be tested at different steps throughout the manufacture of the device, for example before assembly with the optical portion.

In this optoelectronic device, the control portion is “turned over” and connected to the optical portion via the rear face, unlike a smart pixel type conventional device where the connection of the optical portion is done at the front face of the control portion.

This particular architecture of the device allows testing the control portion via its front face at any time during the manufacturing process, in particular before the control portion is assembled with the optical portion. This allows controlling the proper operation of the control portion before assembly with the optical portion. Thus, assembling a defective control portion with a functioning optical portion could be avoided. Advantageously, the architecture of the device enables an early detection of defective or malfunctioning electronic components in the control portion.

Another aspect relates to a method for manufacturing such an optoelectronic device, comprising:
providing the control portion over a first substrate, so that the front face is exposed,
bonding the control portion over a transfer substrate, at the front face,
removing the first substrate so as to expose the rear face of the control portion,
forming the through electrical connections starting from the rear face up to the electrical interconnection level of the control portion,
providing the optical portion over a second substrate, so that the connection face is exposed,
bonding the connection face of the optical portion onto the rear face of the control portion,
removing the second substrate so as to expose an emitter or receiver face of the optical portion.

Thus, the method advantageously allows turning over the control portion to connect it at the rear face with the optical portion, via the through electrical connections. The advantages resulting from the particular architecture of the device, set out hereinabove, apply to the method. Thus, testing at the front face of the control portion could be considered as soon as the control portion is provided, before any assembly or bonding of the control portion with the optical portion. Testing at the front face of the control portion could also be done after assembly, typically after removal of the transfer substrate.

Moreover, in conventional manufacturing method of a smart pixel, since the front face of the control portion is used for bonding and electrical interfacing with the optical portion, it is the rear face which is dedicated for testing of the control portion. In general, through electrical connections are created starting from the rear face up to the electrical interconnection level of the control portion, after bonding with the optical portion. Bonding at the front face is done the earliest in order to preserve the front face from possible damages caused by other handling steps. Thus, the steps of bonding and then forming the through electrical connections are performed in series. This makes the conventional manufacturing method long, with the risk of detecting too late possible malfunctions of the control portion.

On the contrary, according to the method of the present invention, the through electrical connections of the control portion are formed before bonding with the optical portion. Hene, it is possible to treat the control portion and the optical portion separately, in parallel. A parallel treatment allows optimising the equipment set-up time on a manufacturing line. Thus, the duration of the manufacturing process is reduced. The number of steps subsequent to bonding of the optical and control portions is reduced.

Particular advantageous applications of the optoelectronic device and of the manufacturing method relate to the field of smart LEDs and smart pixels.

### BRIEF DESCRIPTION OF THE FIGURES

The aims, objects, as well as the features and advantages of the invention will appear better from the detailed description of embodiments of the latter which are illustrated by the following appended drawings wherein:

FIG. 1 to 12 schematically illustrate steps of manufacturing an optoelectronic device according to an embodiment of the present invention. FIGS. 1 to 7 schematically illustrate steps of manufacturing a control portion of an optoelectronic device according to an embodiment of the present invention. FIG. 8 schematically illustrates an optical portion of an optoelectronic device according to an embodiment of the present invention. FIGS. 9 to 12 schematically illustrate steps of assembling a control portion with an optical portion of an optoelectronic device according to an embodiment of the present invention.

FIG. 13 illustrates in the form of a flowchart a sequence of steps of the method according to an embodiment of the present invention and a sequence of steps of a conventional method, according to the prior art.

The drawings are provided as examples and do not limit the invention. They consist of schematic illustrations intended to facilitate understanding of the invention and are not necessarily to the scale of practical applications. In particular, the dimensions of the different portions of the test and transfer structures and of the LEDs do not necessarily represent reality.

### DETAILED DESCRIPTION

Before starting a detailed review of embodiments of the invention, it is recalled that the invention according to its first aspect comprises in particular the optional features hereinafter which may be used in combination or alternatively.

According to one example, the front face of the control portion has projecting contact pads, intended to be contacted by test probes, said contact pads being connected at the electrical interconnections. These contact pads are typically dimensioned so as to withstand the contact and the pressure exerted by test probes conventionally used for electrical testing. Preferably, these contact pads are specifically intended to perform such an electrical test, unlike the interconnections and/or contact pads of the interconnection level of the control portion.

According to one example, according to the stacking direction z, the device successively comprises: the front face of the control portion, the interconnection level of the control portion, the electronic component level of the control portion, the rear face of the control portion, the connection face of the optical portion, the connection level of the optical portion, the optically-active component level of the optical portion. In this stacking, the control portion is typically turned over with respect to a control portion of a standard smart pixel type device. Thus, the front and rear faces of the control portion are permuted compared to a standard configuration.

According to one example, the optically-active components of the optical portion are GaN-based light-emitting diodes.

According to one example, the electronic components of the control portion comprise transistors, for example MOS transistors or TFT-type transistors (meaning “Thin Film Transistors”).

According to one example, the manufacturing method further comprises forming contact pads projecting from the front face and connected at the interconnection level, said contact pads being intended to be contacted by test probes.

According to one example, the contact pads are formed in openings of the front face, said openings leading into upper metal tracks of the interconnection level. The interconnection level typically comprises a plurality of metal tracks stacked according to z. In such a stacking, the upper metal tracks are typically located the closest to the front face, opposite the electronic components, according to z. Thus, the contact pads at the front face are connected to these upper metal tracks.

According to one example, forming the contact pads comprises a full-plate deposition of a seed layer, a lithography step defining, in a resin layer, contact patterns directly above the openings of the front face, filling said contact patterns with a first metal material or a first plurality of metal materials, for example Cu/Ni/Au or Cn/Ni/SnAg, removing the resin layer exposing portions of the seed layer, outside the contact patterns, and removing the exposed portions off the seed layer.

According to one example, forming the contact pads is performed before bonding the control portion onto the transfer substrate.

According to an alternative example, forming the contact pads is performed after bonding the control portion onto the transfer substrate, and after removal of the transfer substrate.

According to one example, the manufacturing method further comprises a step of testing the control portion by connecting test probes on the contact pads or on upper metal tracks (120a, Msup) of the interconnection level (12). Preferably, this test step is performed before bonding the rear face of the control portion with the connection face of the optical portion. This allows stopping the manufacturing method before bonding in the event of a defective or malfunctioning control portion. At this level, the malfunctioning control portion may be replaced by another functioning control portion in preparation for bonding with the optical portion. Thus, the impact on the costs of the manufacturing method is limited.

According to one example, bonding the control portion onto the transfer substrate is done by interposing a layer between the front face of the control portion and the transfer substrate, said layer being based on an organic or mineral material. The polymer layer typically allows absorbing a topography at the front face, in particular the topography due to the presence of contact pads projecting from the front face. The mineral layer allows supporting a greater thermal budget. It also allows limiting contamination.

According to one example, the manufacturing method further comprises, after removal of the second substrate, forming colour conversion modules starting from the emitter or receiver face of the optical portion, said colour conversion modules being configured to modify a wavelength of the light radiation emitted or received by the optically-active components.

According to one example, the manufacturing method further comprises, after forming the colour conversion modules, forming or bonding a protective transparent layer over said colour conversion modules. The protective transparent layer allows protecting and/or handling the plates bearing the devices.

According to one example, forming the through electrical connections comprises forming by lithography and etching, starting from the rear face, vias patterns exposing lower metal tracks of the interconnection level, said lower metal tracks being preferably located on the side of the electronic components, and filling said vias patterns with a second metal material. The interconnection level typically comprises a plurality of metal tracks stacked according to z. In such a stacking, the lower metal tracks are typically located the closest to the electronic components, opposite the front face, according to z. Thus, the through electrical connections at the rear face are connected to these lower metal tracks.

According to one example, the connection face of the optical portion comprises second contact areas.

According to one example, the manufacturing method further comprises first contact areas over the rear face of the control portion, said first contact areas connecting at least some through electrical connections, said first contact areas being configured to be assembled by a metal-metal bonding or by a hybrid direct bonding with the second contact areas of the connection face of the optical portion.

Except in the case of incompatibility, technical features described in detail for a given embodiment may be combined with the technical features described in the context of other embodiments described as non-limiting example, so as to form another embodiment which is not necessarily illustrated or described. Of course, such an embodiment is not excluded from the invention.

In the present invention, the method is dedicated in particular to testing of the control portions of optoelectronic devices, in particular light-emitting diodes (LED), and in particular smart LEDs or smart pixels. The LEDs present in smart pixels typically have dimensions, in projection in a base plane xy, comprised between 10 μm×10 μm and 300 μm×300 μm.

The invention may be implemented more broadly for different optoelectronic devices, and possibly for electromechanical devices or microsystems MEMS. For example, the invention may be implemented in the context of laser or photovoltaic devices. Other optoelectronic components could perfectly be considered, in particular to make micro-screens. These components may have larger dimensions, in the range of one centimetre.

Unless explicitly mentioned otherwise, it is specified that, in the context of the present invention, the relative arrangement of a third layer interposed between a first layer and a second layer, does not necessarily mean that the layers are directly in contact with each other, but means that the third layer is either directly in contact with the first and second layers, or separate from these by at least one other layer or at least one other element.

Thus, the terms and locutions “bear” and “cover” or “overlay” do not necessarily mean “in contact with”.

The steps of the method as claimed should be understood in a broad sense and may possibly be carried out into several sub-steps.

In the present patent application, the terms “light-emitting diode”, “LED” or simply “diode” are used as synonyms. A “LED” may also be understood as a “micro-LED” or as a “mini-LED”, and possibly as a “micro-screen”. We will talk about a smart LED when a LED is associated with a control portion.

By “optically-active component”, it should be understood a component capable of receiving or emitting light, and/or transforming the properties of the light. Diodes and lasers are examples of optically-active components. Photovoltaic cells are other examples of active components. Photonic phase modulators are also other examples of active components. These examples are not limiting.

By a substrate, a layer, a device, “based” on a material M, it should be understood a substrate, a layer, a device comprising this material M alone or this material M and possibly other materials, for example alloy elements, impurities or doping elements. Thus, a GaN-based diode typically comprises GaN and AlGaN or InGaN alloys.

A reference frame, preferably orthonormal, comprising the axes x, y, z is represented in some appended figures. This reference frame is applicable by extension to the other figures of the same drawing sheet.

In the present patent application, reference will preferably be made to a thickness for a layer and to a height structure or a device. The thickness is considered according to a direction normal to the main plane of extension of the layer, and the height is considered perpendicularly to the base plane xy. Thus, a layer typically has a thickness according to z, when it extends primarily along a plane xy, and a projecting element, for example an insulation wafer, has a height according to z. The relative terms “over”, “under”, “underlying” preferably refer to positions considered according to the direction z.

The dimensional values should be understood within the manufacturing and measurement tolerances.

The terms “substantially”, “about”, “in the range of” mean, when they relate to a value, “within 10%” of this value or, when they relate to an angular orientation, “within 10°” of this orientation. Thus, a direction substantially normal to a plane means a direction having an angle of 90±10° with respect to the plane.

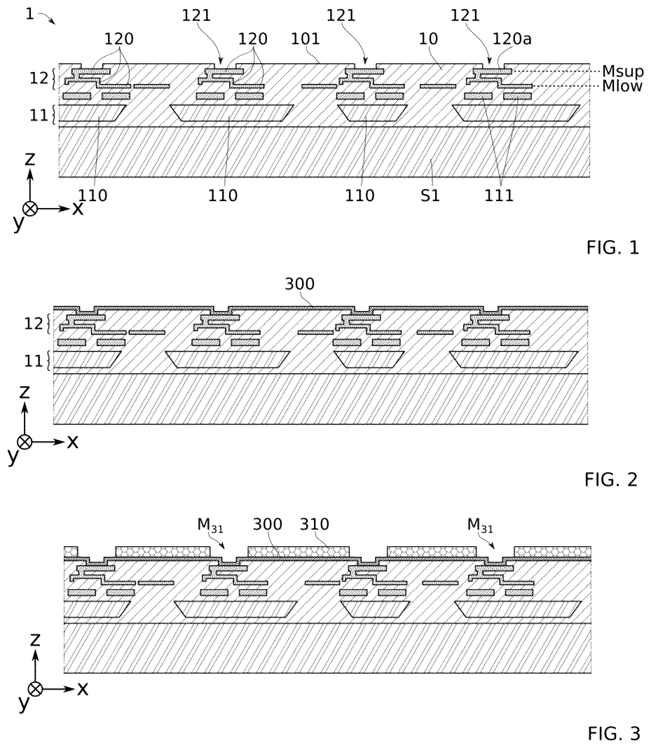

FIG. 1 illustrates a control portion 1 conventionally used for optoelectronic devices of the smart LED or smart pixel type. Thus, this control portion 1 typically comprises an electronic component 110 level 11 topped by an electrical interconnection 120 level 12.

In particular, the level 11 may correspond to a so-called front end-of-line level FEOL (acronym for “Front End of Line”) and the electronic components 110 may, for example, comprise CMOS transistors, for example in the form of integrated microcircuits μIC. In general, such a level 11 is formed directly over a silicon-based substrate S1, for example a solid substrate made of silicon or a substrate made of silicon-on-insulator SOI (acronym for “Silicon On Insulator”). Alternatively, the level 11 may comprise thin film transistors TFT (acronym for “Thin Film Transistor”).

In particular, the level 12 may correspond to a so-called back end-of-line level BEOL (acronym for “Back End Of Line”) and the electrical interconnections 120 may, for example, comprise substantially horizontal metal tracks and vertical vias connecting these metal tracks. The electrical interconnections 120 are typically formed within a matrix 10 made of a dielectric material. In the stacking, the electrical interconnections 120 are generally distributed according to z over several levels called metal levels 1 to N. Thus, a first level of lower metal tracks Mlow is located on the side of the electronic components 110, the closest to these components 110 or a contact level 111 on top of the components 110. A last level of upper metal tracks Msup is located on the side of the front face 101.

Openings 121 are typically formed starting from the front face 101, directly above the upper metallic tracks 120a. The openings 121 lead into said upper metal tracks 120a. These openings 121 will enable the formation of contact pads connected at the interconnection 120 level 12.

FIGS. 2 to 5 illustrate steps of forming these contact pads in the openings 121.

As illustrated in FIG. 2, a seed layer 300 is preferably deposited in a conformal manner over the front face 101 and in the openings 121. This seed layer 300 is typically copper-based. It may be in the form of a bilayer or of a three-layer comprising for example a titanium-based hooking layer, a TiN-based optional layer, and a copper layer for seeding. Preferably, it has a small thickness, for example in the range of a few tens to a few hundred nanometres, and lines the bottom and the walls of the openings 121. The deposition of this seed layer 300 may be done by ECD electrolytic deposition (Electro Chemical Deposition according to the Anglo-Saxon acronym), by chemical vapour deposition (CVD according to the Anglo-Saxon acronym) or by physical vapour deposition (PVD according to the Anglo-Saxon acronym), so as to obtain a seed with a good crystalline quality.

As illustrated in FIG. 3 after the full-plate deposition of the seed layer 300, a resin layer 310 is deposited and then structured by lithography so as to define contact patterns M31 directly over the openings 121. The seed layer 300 is exposed at these contact patterns M31.

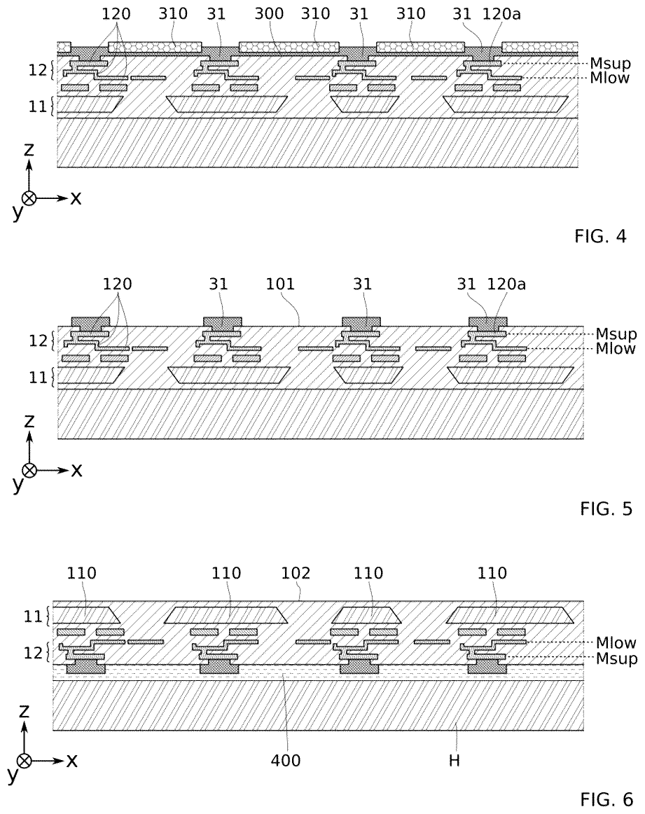

As illustrated in FIG. 4, the contact patterns M31 are filled afterwards by growth of one or more metal material(s), typically with Cu/Ni/Au or Cu/Ni/SnAg multilayers, to form the contact pads 31. Filling may be done by ECD electrolytic deposition so as to obtain a greater metal thickness for the contact pads 31, for example in the range of a few microns. In particular, such a contact pad thickness 31 allows supporting a contact with test probes without damaging the upper metal tracks 120a of the underlying interconnection 120 level 12.

As illustrated in FIG. 5, the resin layer 310 may be removed afterwards, for example by chemical removal, at room temperature or at a temperature (<100° C.). Thus, the portions of the seed layer 300 initially hidden by the resin layer 310 are exposed. These exposed portions of the seed layer 300 are then removed, for example by wet etching, in order to isolate the contact pads 31 from one another (FIG. 5). Upon completion of these steps of forming the contact pads 31, the contact pads 31 typically project from the front face 101. At this level, the control portion may advantageously be tested via the contact pads 31 at the front face 101. An external test module equipped with test probes may be connected to the contact pads 31. If the test reveals a malfunction of this control portion, the manufacturing method is stopped before assembly with the optical portion. The costs are reduced. The replacement of the defective control portion is facilitated. If the result of the test is positive, i.e. if the control portion is functional or sufficiently functional (for example if the yield is enough), the manufactured process is carried on.

As illustrated in FIG. 6, the control portion on its substrate S1 is then turned over and bonded onto a transfer substrate H. Bonding may be done via a polymer-based bonding layer 400. This allows accommodating the topography at the front face 101 due to the presence of the contact pads 31, where appropriate. Alternatively, bonding between the control portion and the transfer substrate H may be done via a mineral bonding layer 400, typically based on silicon oxide. Such a mineral bonding layer 400 allows withstanding higher temperatures than an organic layer. A mineral bonding layer 400 also allows dealing more easily with the problems related to contamination, both within the equipment involved in the manufacturing process, and on the device during manufacture, in particular upon removal of the transfer substrate H. This “mineral” bonding type may be done before or after the formation of the contact pads 31, preferably before the formation of the contact pads 31.

According to an alternative possibility, the contact pads 31 are made only at the end of the manufacturing process. The steps illustrated in FIGS. 2 to 5 are performed later on, typically after removal of the transfer substrate H. This allows facilitating achieving a mineral bonding between the front face 101 of the control portion and the transfer substrate H. This does not prevent testing of the control portion because the latter could be done in particular with proves directly on the upper metal tracks 120a. The flatness defect generated by this test could be suppressed later on during the steps of making the pads 31 (FIGS. 2 to 5), at the end of the process.

After bonding the transfer substrate H, whether via an organic or mineral bonding layer 400, the substrate S1 is removed, for example by trimming. Thus, the rear face 102 of the control portion is exposed.

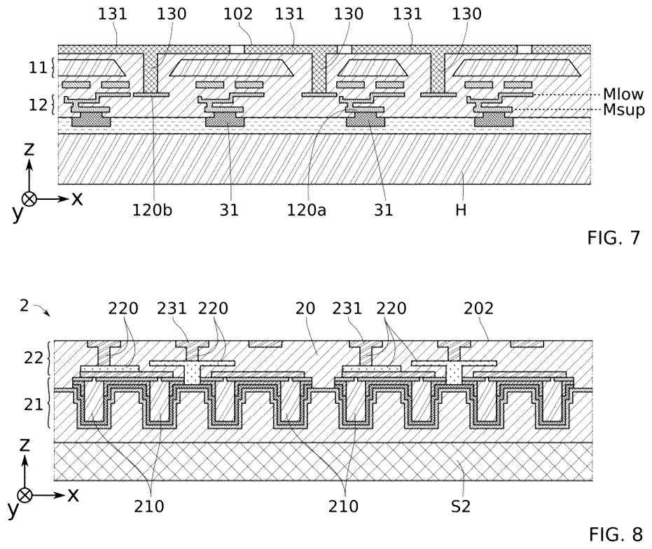

As illustrated in FIG. 7, through electrical connections 130, for example in the form of vias, are formed starting from the rear face 102 up to the electrical interconnection 120 level 12. The through electrical connections 130 typically cross the electronic component 110 level 11, according to z. Preferably, they are connected to lower metal tracks 120b of the first metal level Mlow, opposite the upper metal tracks 120a of the last metal level Msup connected to the contact pads 31. The through electrical connections 130 or vias may be formed by lithography and etching throughout the dielectric matrix 10, according to microelectronics standards processes. If the through electrical connections 130 cross a conductive or semiconductor material, for example a semiconductor thin layer used to form electronic components 110 according to a PDSOI technology (acronym for “Partially Depleted Silicon On Insulator”) or FDSOI (acronym for “Fully Depleted Silicon On Insulator”), these through electrical connections 130 may be insulated by an insulating sheath.

Afterwards, contact areas 131 are formed over the rear face 102. The metal PVD deposition, for example successively based on copper and titanium, is typically performed at the rear face 102 and then structured by photolithography and etching to form these contact areas 131 of the control portion. The contact areas 131 are configured to connect the through electrical connections 130. They are intended to electrically connect the optical portion of the optoelectronic device during assembly of the control portion with the optical portion.

According to an alternative possibility, the contact areas 131 are formed in the same manner as the contact pads 31, with a prior deposition of a seed layer then a localised filling with metal by photolithography and electrochemical deposition, then a partial removal of the seed layer, outside the contact areas 131.

The control portion 1 is typically configured to control or pilot the optical portion 2.

As illustrated in FIG. 8, the optical portion 2 is manufactured independently of the control portion 1. Thus, this optical portion 2 typically comprises a level 21 of optically-active components 210 topped by a level 22 of electrical connections 220.

In particular, the level 21 may comprise light-emitting diodes, preferably μLEDs or nanowire-based LEDs. In general, such a level 21 is formed directly over a specific initial substrate, for example based on silicon or sapphire (not illustrated), and then transferred onto a substrate S2 in order to form the electrical connection 220 level 22 at “the rear face” of the optically-active component 210 level 21 after removal of the initial substrate.

In particular, the level 22 may comprise electrical connections 220 in the form of substantially horizontal metal tracks and of vertical vias connecting these metal tracks. The electrical connections 220 are typically formed within a matrix 20 made of a dielectric material. Contact pads or areas 231 intended to electrically connect the control portion of the optoelectronic device during assembly of the optical portion with the control portion, are typically provided at a so-called the connection face 202 of the optical portion 2.

According to one possibility, the contact areas 231 are formed in the same manner as the contact pads 31, with a prior deposition of a seed layer and then a localised filling with metal by photolithography and electrochemical deposition, and then a partial removal of the seed layer, outside the contact areas 231.

Advantageously, the control portion 1 illustrated in FIG. 7 and the optical portion 2 illustrated in FIG. 8 are manufactured in parallel to one another, i.e. substantially at the same time. This allows reducing the overall duration of the process of manufacturing the optoelectronic device. This allows optimising the use of the manufacturing industrial equipment.

According to one possibility, the contact areas 131 and the contact areas 231 are formed simultaneously and/or in the same piece of equipment according to the same process, typically by performing full-plate depositions over the faces 102, 202, followed by structuring by photolithography and etching, and/or by chemical-mechanical polishing CMP (acronym for “Chemical Mechanical Polishing”). This allows optimising the use of equipment and reducing the duration of the manufacturing method.

According to one possibility, the contact pads 31 and the contact areas 231 are formed simultaneously and/or in the same piece of equipment according to the same process, typically by performing full-plate depositions over the faces 101, 202, followed by structuring by photolithography and etching. This allows optimising the use of the equipment and reducing the duration of the manufacturing method.

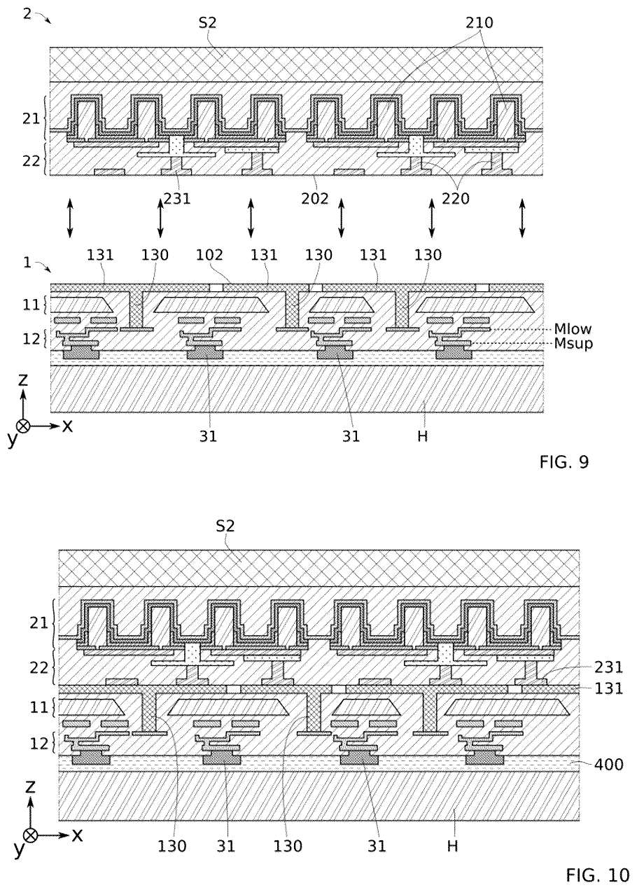

As illustrated in FIG. 9, the connection face 202 of the optical portion 2 is set afterwards opposite the rear face 102 of the control portion 1, in preparation for the assembly of the optical portion 2 with the control portion 1. The contact areas 231 are typically aligned with the contact areas 131.

As illustrated in FIG. 10, the optical portion 2 and the control portion 1 are then assembled, for example by hybrid direct bonding, by thermocompression or by metal-metal eutectic bonding, at the faces 102, 202, at least partially via the contact areas 131, 231.

At this level, the stack successively comprises according to z: the transfer substrate H, the polymer or oxide bonding layer 400, the contact pads 31, the electrical interconnection level 12, the electronic component level 11, the contact areas 131 of the control portion, the contact areas 231 of the optical portion, the electrical connection level 22, the optically-active component level 21, the substrate S2.

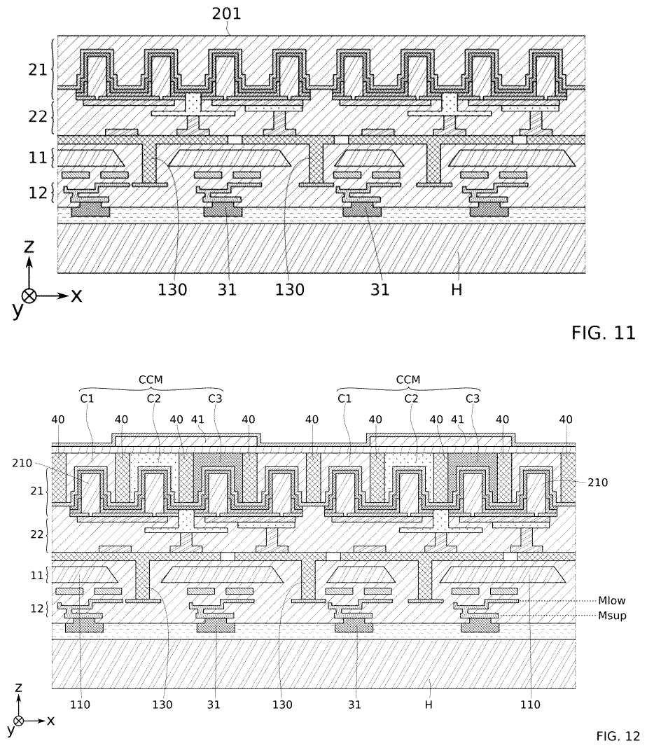

As illustrated in FIG. 11, the substrate S2 may then be removed, for example by trimming, in order to expose the “front face” of the optical portion, typically a light emitter or receiver face 201.

As illustrated in FIG. 12, a colour conversion module CCM may be formed afterwards at the optically-active components, starting from the face 201. In a known manner, such a module is configured to convert a light emitted according to an initial wavelength by the optically-active components 210, into light having one or more different wavelength(s), typically first, second and third wavelengths corresponding to the blue (B), green (G) and red (R) colours. This allows forming RGB subpixels of a pixel of a display screen for example. Such a module CCM is typically formed by localised deposition of different nanoparticles C1, C2, C3 over different optically-active components 210 intended to form the subpixels. The nanoparticles C1, C2, C3 typically form “quantum dots” (QD) enabling the wavelength conversions. Trenches 40 may be formed to separate the different deposition areas of the nanoparticles C1, C2, C3. Alternatively, the module CMM may, for example, comprise coloured filters C1, C2, C3.

After forming the colour conversion module(s) CCM, a transparent layer for protection and/or facilitating handling of the optoelectronic device for example made of glass may be bonded onto the module(s) CCM. This protective layer is typically bonded by organic bonding onto the module(s) CCM, in order to preserve the nanoparticles C1, C2, C3. Afterwards, the transfer substrate H is typically removed.

According to one possibility, if the contact pads 31 have not been formed beforehand, the contact pads 31 are formed after removal of the transfer substrate H, typically according to the steps illustrated in FIGS. 2 to 5. Advantageously, the protective transparent layer may then serve as a structural support after removal of the substrate H to make the pads 31.

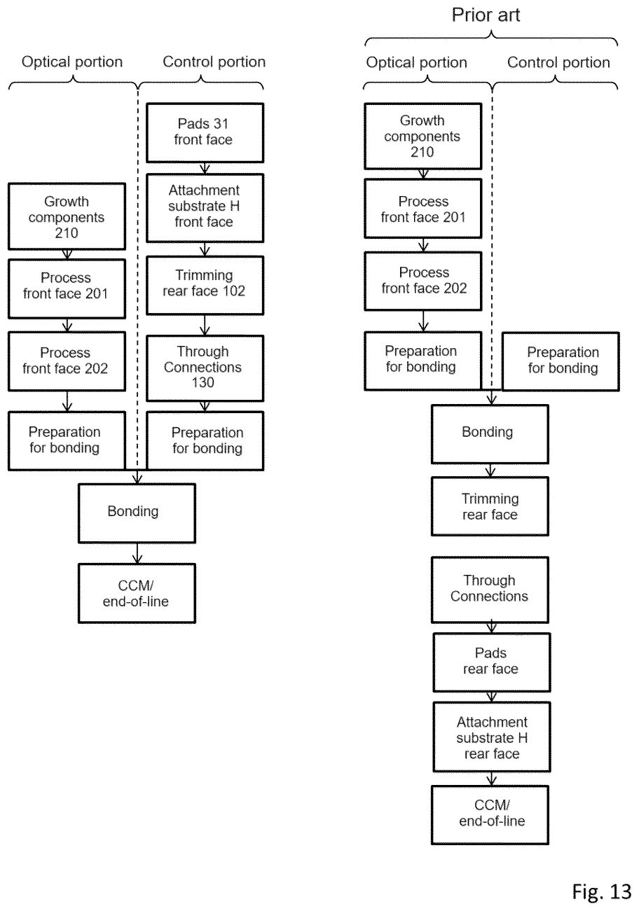

FIG. 13 illustrates in the form of flowcharts a sequence of steps of the method according to the present invention and a sequence of steps of a conventional method, according to the prior art, for comparison. It appears that a multitude of steps of the method according to the invention, illustrated by the flowchart to the left in FIG. 13, may be conducted prior to bonding of the optical portion and of the control portion. Thus, the optical portion and the control portion may advantageously be treated separately, in parallel to one another, before bonding. In particular, forming the pads 31 at the front face and forming the through connections 130 at the rear face of the control portion may be performed before bonding the optical portion on the control portion. Only the steps of forming the colour conversion module and the end-of-line steps are performed after bonding the optical portion on the control portion.

On the contrary, according to the conventional process illustrated by the flowchart to the right in FIG. 13, it is necessary to proceed with bonding of the optical portion at the front face of the control portion, before forming contact pads at the rear face. Afterwards, the device should be turned over to continue performing the steps of forming the colour conversion module and the end-of-line steps. The optical portion and the control portion are herein treated one after another, in series.

Alternatively, when the formation of the pads 31 at the front face is performed at the end of the process, after removal of the substrate H, the method according to the invention features a better compatibility with the manufacturing equipment and an improved mineral bonding.

As illustrated throughout the preceding examples, the particular architecture of the optoelectronic device and the method for manufacture thereof according to the invention therefore advantageously allow optimising the manufacturing time and costs of such a device, for example of the smart pixel type. However, the invention is not limited to the previously-described embodiments.

1. An optoelectronic device comprising a control portion and an optically-active portion (optical portion), stacked according to a stacking direction (z), wherein:
the control portion comprises at least:
a level of electronic components configured to execute logical functions, and
a level of electrical interconnections connected to said electronic component level and defining a first face of the control portion (front face),
the optical portion comprising at least:
a level of optically-active components configured to emit or receive a light radiation,
a level of electrical connections connected to said optically-active component level and defining a second face of the optical portion (connection face),
and wherein the control portion and the optical portion are associated so that the electrical interconnection level of the control portion is electrically connected to the electrical connection level of the optical portion, and wherein the control portion comprises so-called through connections extending from the interconnection level to a second face of the control portion opposite to the first face (rear face), and in that said rear face of the control portion corresponds to the connection face of the optical portion, so that the electrical interconnection level of the control portion is electrically connected to the electrical connection level of the optical portion via said through connections.

2. The device according to claim 1, wherein the front face of the control portion has projecting contact pads, configured to be contacted by test probes, said contact pads being connected at the electrical interconnection level.

3. The device according to claim 1, wherein, according to the stacking direction (z), the device successively comprises: the front face of the control portion, the interconnection level of the control portion, the electronic component level of the control portion the rear face of the control portion the connection face of the optical portion, the connection level of the optical portion the optically-active component level of the optical portion.

4. The device according to claim 1, wherein the optically-active components of the optical portion are GaN-based light-emitting diodes.

5. The device according to claim 1, wherein the electronic components of the control portion comprise transistors.

6. A method for manufacturing an optoelectronic device according to claim 1, comprising:
providing the control portion over a first substrate so that the front face is exposed,
bonding the control portion over a transfer substrate (H), at the front face
removing the first substrate so as to expose the rear face of the control portion,
forming the through electrical connections starting from the rear face up to the electrical interconnection level of the control portion,
providing the optical portion over a second substrate, so that the connection face is exposed,
bonding the connection face of the optical portion onto the rear face of the control portion,
removing the second substrate so as to expose an emitter or receiver face of the optical portion.

7. The method according to claim 6, further comprising forming contact pads projecting from the front face and connected at the interconnection level, said contact pads being configured to be contacted by test probes.

8. The method according to claim 7, wherein the contact pads are formed in openings of the front face said openings leading into upper metal tracks of the interconnection level.

9. The method according to claim 8, wherein forming the contact pads comprises a full-plate deposition of a seed layer, a lithography step defining, in a resin layer, contact patterns directly over the openings of the front face, filling said contact patterns with a first metal material, removing the resin layer exposing portions of the seed layer, outside the contact patterns, and removing the exposed portions of the seed layer.

10. The method according to claim 7, wherein forming the contact pads is performed before bonding the control portion onto the transfer substrate (H).

11. The method according to claim 7, wherein forming the contact pads is performed after bonding the control portion onto the transfer substrate (H), and after removing the transfer substrate (H).

12. The method according to claim 7, further comprising a step of testing the control portion by connecting test probes on the contact pads or on upper metal tracks of the interconnection level.

13. The method according to claim 6, wherein bonding the control portion onto the transfer substrate (H) is done by interposing a layer between the front face of the control portion and the transfer substrate (H), said layer being based on an organic or mineral material.

14. The method according to claim 6, further comprising, after removing the second substrate, forming colour conversion modules starting from the emitter or receiver face of the optical portion, said colour conversion modules being configured to modify a wavelength of the light radiation emitted or received by the optically-active components

15. The method according to claim 14, further comprising, after forming the colour conversion modules forming or bonding a protective transparent layer over said colour conversion modules.

16. The method according to claim 6, wherein forming the through electrical connections comprises forming by lithography and etching, starting from the rear face, vias patterns exposing lower metal tracks of the interconnection level, said lower metal tracks being preferably located on the side of the electronic components, and filling said vias patterns with a second metal material.

17. The method according to claim 16, wherein the connection face of the optical portion comprises second contact areas said method further comprising forming first contact areas over the rear face of the control portion, said first contact areas connecting at least some through electrical connections, said first contact areas being configured to be assembled by a hybrid direct bonding with the second contact areas of the connection face of the optical portion.
